(19) United States
(12) Patent Application Publication
(10) Pub. No.: US 2018/0122911 A1
(43) Pub. Date: May 3, 2018

(54) SEMICONDUCTOR DEVICE AND METHOD OF MANUFACTURING THE SAME

(71) Applicant: HYUNDAI MOTOR COMPANY, Seoul (KR)

(72) Inventors: NackYong JOO, Hanam-si (KR); Youngkyun JUNG, Seoul (KR); Junghee PARK, Suwon-si (KR); JongSeok LEE, Suwon-si (KR); Dae Hwan CHUN, Gwangmyeong-si (KR)

(21) Appl. No.: 15/372,078

(22) Filed: Dec. 7, 2016

(30) Foreign Application Priority Data
Oct. 27, 2016 (KR) 10-2016-0141195

(51) Int. Cl. H01L 29/40; H01L 29/06; H01L 21/761; H01L 21/765; H01L 29/16

(52) U.S. Cl. CPC H01L 29/402; H01L 29/0619; H01L 29/7811; H01L 21/765; H01L 29/1608; H01L 21/761

(57) ABSTRACT

A semiconductor device according to an exemplary embodiment of the present invention includes: a current applying region; and a termination region disposed at an end portion of the current applying region. The termination region includes: an n− type layer disposed on a first surface of an n+ type silicon carbide substrate; a p type termination structure disposed in the n− type layer; and a lower gate runner disposed on the p type termination structure such that the lower gate runner overlaps the p type termination structure.

### CROSS-REFERENCE TO RELATED APPLICATION

This application claims the benefit of priority to Korean Patent Application No. 10-2016-0141195, filed in the Korean Intellectual Property Office on Oct. 27, 2016, the entire content of which is incorporated herein by reference.

### TECHNICAL FIELD

The present disclosure relates to a semiconductor device including silicon carbide (SiC), and a method of manufacturing the same.

### BACKGROUND

In accordance with the recent trend towards increased size and capacity of application equipment, there has been increased demand for a semiconductor device for electric power having a high breakdown voltage, a high current, and a high-speed switching characteristic.

Since a semiconductor device for electric power including silicon carbide (SiC) has excellent characteristics compared to a semiconductor device for electric power including silicon (Si) according to the related art, the semiconductor device for electric power including silicon carbide (SiC) has been researched as a semiconductor device for electric power. The semiconductor device for electric power including silicon carbide (SiC) is capable of satisfying a high breakdown voltage, a high current, and a high-speed switching characteristic.

Furthermore, the semiconductor device includes a current applying region, which is a current flowing region, and a termination region, which is a region disposed at an end portion of the current applying region, when a forward-directional voltage is applied.

In the termination region, a curve of a PN junction exists, so that when a reverse-directional voltage is applied, a depleted layer is formed along the curve of the PN junction, and an electric field is concentrated in the curve of the PN junction, so that a breakdown voltage of the semiconductor device is decreased.

In this respect, the semiconductor device adopts various termination structures in order to prevent a breakdown voltage from being decreased by the electric field concentrated in the termination region when the reverse-directional voltage is applied.

The above information disclosed in this Background section is only for enhancement of understanding of the background of the disclosure and therefore it may contain information that does not form the prior art that is already known in this country to a person of ordinary skill in the art.

### SUMMARY

The present disclosure has been made in an effort to provide a semiconductor device where a distribution of an electric field in a termination region may be uniform. An exemplary embodiment of the present disclosure provides a semiconductor device, including: a current applying region; and a termination region disposed at an end portion of the current applying region. The termination region includes: an n− type layer disposed on a first surface of an n+ type silicon carbide substrate; a p type termination structure disposed in the n− type layer; and a lower gate runner overlapping the p type termination structure, and disposed on the p type termination structure. The termination region may further include an upper gate runner which is in contact with the lower gate runner.

A p type region, which is disposed in a side surface of a second trench adjacent to the termination region, may be extended to the termination region, and may be spaced apart from the p type termination structure.

The p type termination structure may include a plurality of regions, into which p type ions are injected, and the regions, into which the p type ions are injected, may be spaced apart from each other.

The current applying region and the termination region may include a drain electrode disposed in a second surface of the n+ type silicon carbide substrate.

The current applying region may further include: the n− type layer disposed on the first surface of the n+ type silicon carbide substrate; and a gate electrode and a source electrode, which are disposed on the n− type layer and are insulated from each other.

The gate electrode and the lower gate runner may include the same material.

The source electrode and the upper gate runner may include the same material.

The current applying region may further include: a first trench disposed in the n− type layer; the p type region disposed in a side surface of the first trench; and an n+ type region disposed in the side surface of the first trench and disposed within the p type region, and the gate electrode may be disposed within the first trench, and the source electrode may be disposed on the n+ type region, on the gate electrode, and on the p type region.

The current applying region may further include a p+ type region, which is disposed within the p type region, and is disposed in a side surface of the n+ type region.

The current applying region may further include: a first trench and a second trench, which are disposed in the n− type layer, and are spaced apart from each other; a p type region disposed in a lower portion and both side surfaces of the second trench; and an n+ type region disposed on the p type region and the n− type layer, and the gate electrode may be disposed within the first trench, and the source electrode may be disposed on the n+ type region, on the gate electrode, and within the second trench.

The current applying region may further include a p+ type region disposed between a lower surface of the second trench and the p type region.

The current applying region may further include: the n− type layer disposed on the first surface of the n+ type silicon carbide substrate; a plurality of p type regions, which are disposed within the n− type layer, and are spaced apart from each other; and a source electrode disposed on the n− type layer and on the p type region.

Another exemplary embodiment of the present disclosure provides a method of manufacturing a semiconductor device, the method including: forming an n− type layer in a first surface of an n+ type silicon carbide substrate including a current applying region and a termination region disposed at an end portion of the current applying region; forming an n+ type region on the n− type layer of the current applying region; forming a first trench and a second trench, which are spaced apart from each other, in the n− type layer of the current applying region by etching the n+ type region and the n− type layer; forming a p type region in a lower portion and both side surfaces of the second trench, and forming a p type termination structure in the n− type layer of the termination region; forming a gate electrode within the first trench, and forming a lower gate runner, which overlaps the p type termination structure and is disposed on the p type termination structure; forming a source electrode on the n+ type region, on the gate electrode, and within the second trench; and forming a drain electrode in a second surface of the n+ type silicon carbide substrate.

The forming of the source electrode may include forming an upper gate runner, which is in contact with the lower gate runner, in the termination region.

According to the exemplary embodiment of the present disclosure, it is possible to make a distribution of an electric field be uniform in a lower portion of the termination structure by disposing the gate runner so as to overlap the termination structure in the termination region of the semiconductor device, and disperse the forming of the depleted layer. Accordingly, it is possible to increase a breakdown voltage of the semiconductor device.

Further, the gate runner is disposed so as to overlap the termination structure in the termination region of the semiconductor device, thereby decreasing an area of the semiconductor device.

### BRIEF DESCRIPTION OF THE DRAWINGS

FIG. 1 is a diagram illustrating an example of a cross-section of a semiconductor device according to an exemplary embodiment of the present disclosure.

FIG. 2 is a graph illustrating a result of a simulation of breakdown voltages of the semiconductor device according to the exemplary embodiment of the present disclosure and a semiconductor device according to the Comparative Example.

FIG. 3 is a diagram illustrating a result of a simulation of an electric field distribution and the forming of a depleted layer in a termination region of the semiconductor device according to the Comparative Example.

FIG. 4 is a diagram illustrating a result of a simulation of an electric field distribution and the forming of a depleted layer in a termination region of the semiconductor device according to the exemplary embodiment of the present disclosure.

FIGS. 5 to 9 are diagrams illustrating an example of a method of manufacturing a semiconductor device according to an exemplary embodiment of the present disclosure.

FIG. 10 is a diagram illustrating an example of a cross-section of a semiconductor device according to another exemplary embodiment of the present disclosure.

FIG. 11 is a diagram illustrating an example of a cross-section of a semiconductor device according to still another exemplary embodiment of the present disclosure.

### DETAILED DESCRIPTION OF THE EMBODIMENTS

Exemplary embodiments of the present disclosure will be described in detail with reference to the accompanying drawings. As those skilled in the art would realize, the described embodiments may be modified in various different ways, all without departing from the spirit or scope of the present disclosure. The exemplary embodiments that are disclosed herein are provided so that the disclosed contents may become thorough and complete and the spirit of the present disclosure may be sufficiently understood to a person of an ordinary skill in the art.

In the drawings, the thicknesses of layers and regions are exaggerated for clarity. In addition, in the case when it is mentioned that a layer is present “on” the other layer or a substrate, the layer may be directly formed on the other layer or the substrate or a third layer may be interposed therebetween. Throughout the specification, like reference numerals designate like constituent elements throughout the specification.

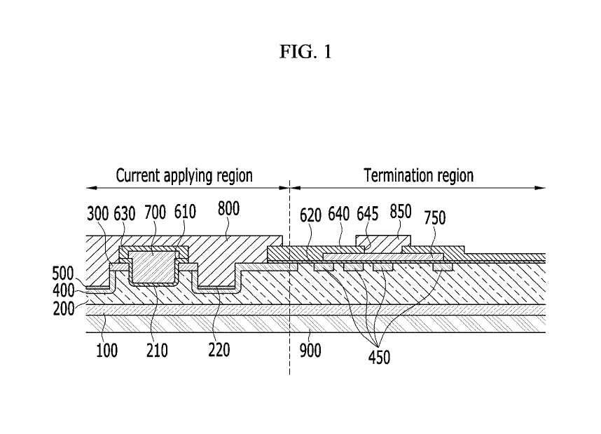

FIG. 1 is a diagram illustrating an example of a cross-section of a semiconductor device according to an exemplary embodiment of the present disclosure.

Referring to FIG. 1, a semiconductor device according to an exemplary embodiment of the present disclosure includes a current applying region and a termination region. The current applying region is a current flowing region, and the termination region is a region disposed at an end portion of the current applying region, when a forward-directional voltage is applied.

The semiconductor device according to the exemplary embodiment of the present disclosure includes an n+ type silicon carbide substrate 100, an n− type layer 200, an n+ type region 300, a p type region 400, a p+ type region 500, a p type termination structure 450, a gate electrode 700, a lower gate runner 750, an upper gate runner 850, a source electrode 800, and a drain electrode 900.

A particular structure of the semiconductor device according to the exemplary embodiment of the present disclosure will be described below.

The n− type layer 200 is disposed on a first surface of the n+ type silicon carbide substrate 100.

A first trench 210 and a second trench 220, which are spaced apart from each other, are disposed in the n− type layer 200 of the current applying region. Depths of the first trench 210 and the second trench 220 may be the same as each other.

The n+ type region 300 is disposed between the first trench 210 and the second trench 220. The p+ type region 500 is disposed on a lower surface of the second trench 220, and the p type region 400 is disposed on a side surface of the second trench 220 and a lower portion of the p+ type region 500. The n− type layer 200 is disposed between the p type region 400 and a side surface of the first trench 210, and the n+ type region 300 is disposed between the p type region 400 and the n− type layer 200.

A gate insulating layer 610 is disposed inside the first trench 210, and the gate electrode 700 is disposed on the gate insulating layer 610. The gate electrode 700 is filled inside the first trench 210, and protrudes to the outside of the first trench 210. The gate electrode 700 may include polysilicon or a metal.

An oxidation layer 630 is disposed on the gate electrode 700. The oxidation layer 630 covers a side surface of the gate electrode 700. The source electrode 800 is disposed on the n+ type region 300, on the oxidation layer 630, and inside the second trench. The source electrode 800 may include an ohmic metal.

In another exemplary embodiment, the second trench 220 may be omitted. In this case, the p type region 400 is disposed in the side surface of the first trench 210. The n+ type region 300 is disposed in the side surface of the first trench 210, and is disposed within the p type region 400. The p+ region 500 is disposed within the p type region 400, and is disposed in a side surface of the n+ type region 300. The source electrode 800 is disposed on the n+ type region 300, on the oxidation layer 630, on the p+ type region 500, and on the p type region 400.

The p type termination structure 450 is disposed in the n− type layer 200 in the termination region. The p type termination structure 450 includes a plurality of regions, into which p type ions are injected, and the regions, into which the p type ions are injected, are spaced apart from each other by an interval.

The p type region 400 disposed in the side surface of the second trench 220 adjacently disposed to the termination region is extended to the termination region, and is spaced apart from the p type termination structure 450. A thickness of the region, into which the p type ions are injected and which forms the p type termination structure 450, is smaller than depths of the first trench 210 and the second trench 220. Further, the thickness of the region, into which the p type ions are injected and which forms the p type termination structure 450, may be the same as a thickness of a portion of the p type region 400 extended to the termination region.

A termination insulating layer 620 is disposed on the p type termination structure 450 and the n− type layer 200 of the termination region, and the lower gate runner 750 is disposed on the termination insulating layer 620. The termination insulating layer 620 may include the same material as that of the gate insulating layer 610. The lower gate runner 750 includes the same material as that of the gate electrode 700, and overlaps the p type termination structure 450.

A termination oxidation layer 640 is disposed on the lower gate runner 750 and the termination insulating layer 620, and the upper gate runner 850 is disposed on the termination oxidation layer 640. The termination oxidation layer 640 may include the same material as that of the oxidation layer 630. The upper gate runner 850 may include the same material as that of the source electrode 800.

The termination oxidation layer 640 is formed with a contact opening 645 exposing a part of the lower gate runner 750, and the upper gate runner 850 is in contact with the lower gate runner 750 through the contact opening 45. The lower gate runner 750 and the upper gate runner 850 serve to rapidly apply a gate voltage to the gate electrode 700.

The drain electrode 900 is disposed on a second surface of the n+ type silicon carbide substrate 100. The drain electrode 900 may include an ohmic metal. Here, the second surface of the n+ type silicon carbide substrate 100 is disposed at an opposite side of the first surface of the n+ type silicon carbide substrate 100.

The lower gate runner 750 and the upper gate runner 850 overlap the p type termination structure 450, so that an inductive voltage is formed in the p type termination structure 450 by the voltage applied to the gate electrode. An electric field is uniformly distributed in a lower portion of the p type termination structure 450 by the inductive voltage, and the forming of the depleted layer is dispersed. Accordingly, a breakdown voltage of the semiconductor device may be increased.

Further, in the related art, the gate runner is disposed between the current applying region and the termination region, but in the present exemplary embodiment, the lower gate runner 750 and the upper gate runner 850 overlap the p type termination structure 450. Accordingly, in the present exemplary embodiment, it is possible to decrease an area of the semiconductor device.

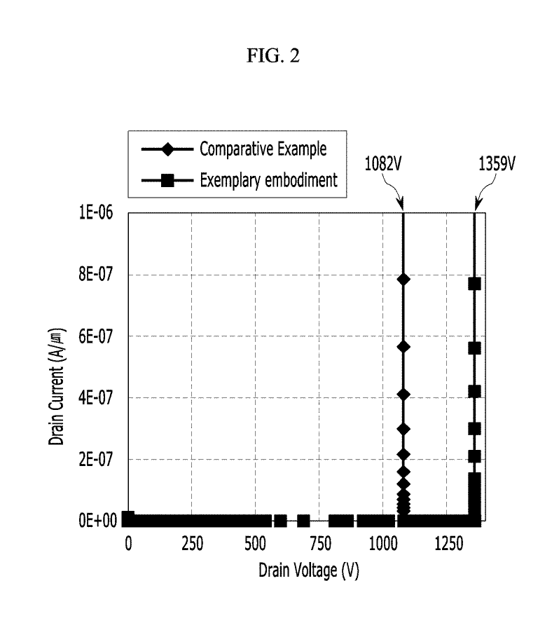

Next, a characteristic of the semiconductor device according to the exemplary embodiment of the present invention will be described with reference to FIGS. 2 to 4.

The characteristics of the semiconductor device according to the exemplary embodiment of the present disclosure and a semiconductor device according to a Comparative Example will be compared and described with reference to FIGS. 2 to 4. Here, the semiconductor device according to the Comparative Example has a structure in which a gate runner is disposed between a current applying region and a termination region. That is, the semiconductor device according to the Comparative Example has a structure in which the gate runner does not overlap a termination structure disposed in the termination region.

FIG. 2 is a graph illustrating a result of a simulation of breakdown voltages of the semiconductor device according to the present exemplary embodiment and the semiconductor device according to a Comparative Example.

Referring to FIG. 2, a breakdown voltage of the semiconductor device according to the present exemplary embodiment is represented as 1,359 V, and a breakdown voltage of the semiconductor device according to the Comparative Example is represented as 1,082 V. That is, it can be seen that the breakdown voltage of the semiconductor device according to the present exemplary embodiment is increased by about 26% relative to that of the semiconductor device according to the Comparative Example. Further, it is possible to decrease a thickness of the n− type layer of the semiconductor device according to an increase in the breakdown voltage, thereby decreasing on-resistance of the semiconductor device.

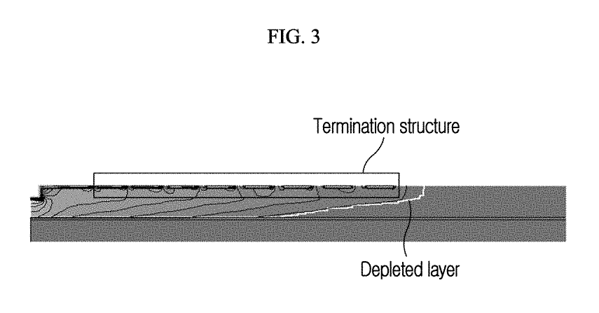

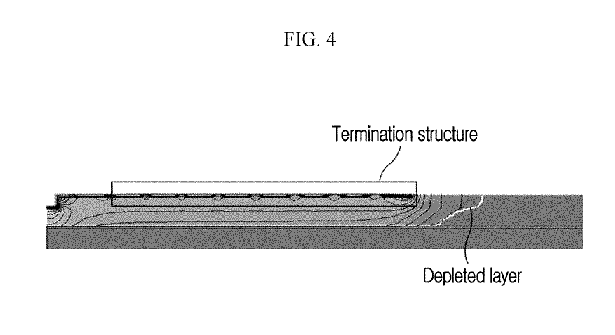

FIG. 3 is a diagram illustrating a result of a simulation of an electric field distribution and the formation of a depleted layer in the termination region of the semiconductor device according to the Comparative Example. FIG. 4 is a diagram illustrating a result of a simulation of an electric field distribution and the formation of a depleted layer in the termination region of the semiconductor device according to the present exemplary embodiment.

Referring to FIGS. 3 and 4, it can be seen that a depleted layer is formed in the termination region of each semiconductor device. In a case of the semiconductor device according to the Comparative Example, it can be seen that an electric field and a depleted layer are weakly present in the outermost region of the termination structure, compared to other regions. On the contrary, in the case of the semiconductor device according to the present exemplary embodiment, it can be seen that an electric field and a depleted layer are equally present even in the outermost region of the termination structure, compared to the other regions. Accordingly, in the case of the semiconductor device according to the present exemplary embodiment, it can be seen that the depleted layer is widely distributed in the outermost region of the termination structure.

Next, a method of manufacturing a semiconductor device according to an exemplary embodiment of the present disclosure will be described in detail with reference to FIGS. 5 to 9, and 1.

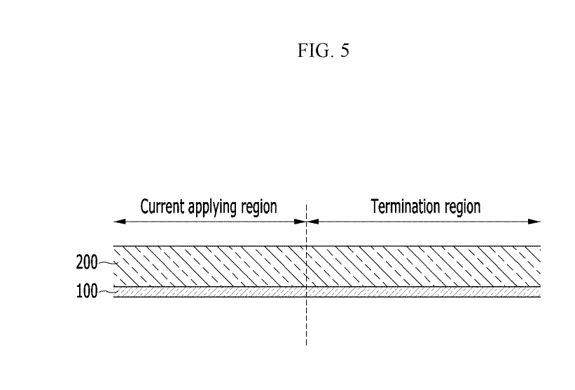

FIGS. 5 to 9 are diagrams illustrating an example of a method of manufacturing a semiconductor device according to an exemplary embodiment of the present disclosure.

Referring to FIG. 5, after the n+ type silicon carbide substrate 100 is prepared, the n− type layer 200 is formed on a first surface of the n+ type silicon carbide substrate 100.

The n+ type silicon carbide substrate 100 and the n− type layer 200 include a current applying region and a termination region disposed at an end portion of the current applying region. The n− type layer 200 may be formed by epitaxial growth or by injecting n− type ions.

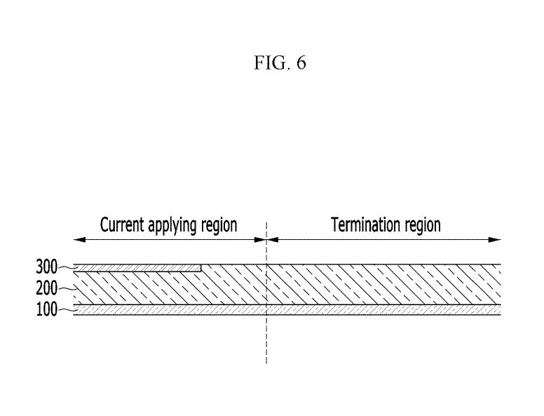

Referring to FIG. 6, the n+ type region 300 is formed in the current applying region.

The n+ type region 300 is formed by injecting n+ type ions into an upper surface of the n− type layer 200 in the current applying region.

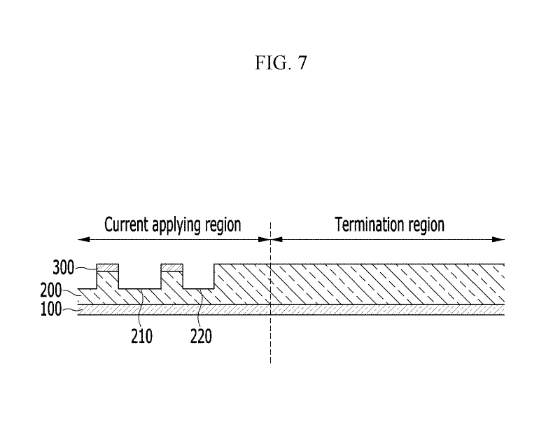

Referring to FIG. 7, the first trench 210 and the second trench 220 are formed in the n− type layer 200 in the current applying region.

The first trench 210 and the second trench 220 are formed by etching the n+ type region 300 and the n− type layer 200 in the current applying region. The first trench 210 and the second trench 220 may be spaced apart from each other, and depths of the first trench 210 and the second trench 220 may be the same as each other.

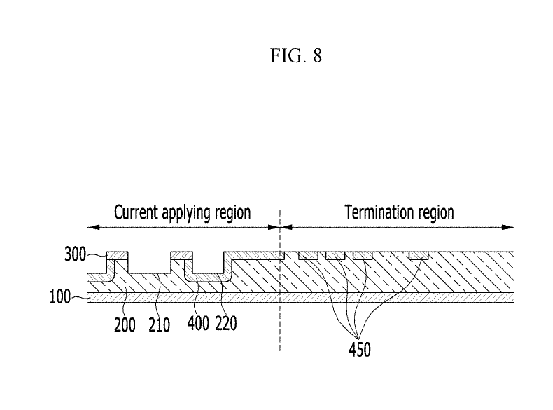

Referring to FIG. 8, the p type region 400 is formed in the current applying region, and the p type termination structure 450 is formed in the termination region.

The p type region 400 is formed by injecting p type ions into the lower surface and the side surface of the second trench 220. Further, the p type region 400 disposed in the side surface of the second trench 220 adjacently disposed to the termination region is extended to the termination region, and is spaced apart from the p type termination structure 450.

The p type termination structure 450 is formed by injecting p type ions into an upper surface of the n− type layer 200 in the termination region. The p type termination structure 450 includes a plurality of regions, into which p type ions are injected, and the regions, into which the p type ions are injected, are spaced apart from each other by a predetermined interval.

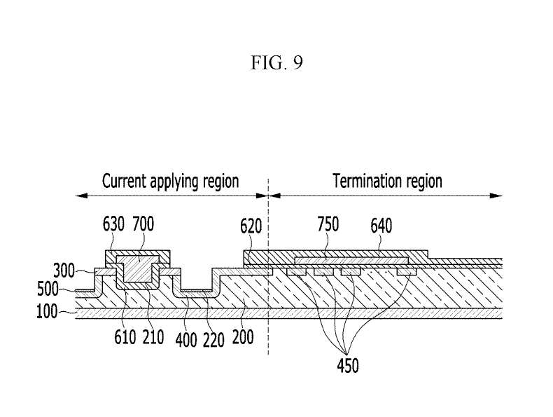

Referring to FIG. 9, the p+ type region 500 is formed under a lower surface of the second trench 220. The p+ type region 500 is formed by injecting p+ type ions into the lower surface of the second trench 220.

Next, the gate insulating layer 610 is formed inside the first trench 210, and the termination insulating layer 620 is formed on the p type termination structure 450 and the n− type layer 200 in the termination region. The gate insulating layer 610 and the termination insulating layer 620 may include the same material.

Next, the gate electrode 700 is formed on the gate insulating layer 610, and the lower gate runner 750 is formed on the termination insulating layer 620. The lower gate runner 750 overlaps the p type termination structure 450. The gate electrode 700 and the lower gate runner 750 may include polysilicon or a metal.

Next, the oxidation layer 630 is formed on the gate electrode 700, and the termination oxidation layer 640 is formed on the termination insulating layer 620 and the lower gate runner 750.

Referring to FIG. 1, after the contact opening 645 is formed in the termination oxidation layer 640, the source electrode 800 is formed in the current applying region, and the upper gate runner 850 is formed in the termination region. Next, the drain electrode 900 is formed on the second surface of the n+ type silicon carbide substrate 100.

The source electrode 800 is formed on the n+ type region 300, on the oxidation layer 630, and inside the second trench. The upper gate runner 850 is formed on the termination oxidation layer 640, and is in contact with the lower gate runner 750 through the contact opening 645. The source electrode 800, the upper gate runner 850, and the drain electrode 900 may include an ohmic metal.

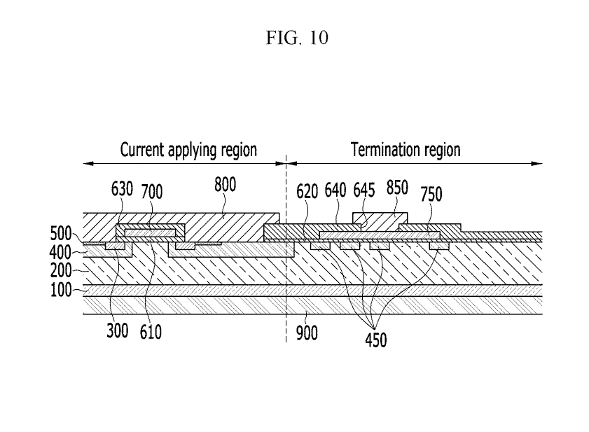

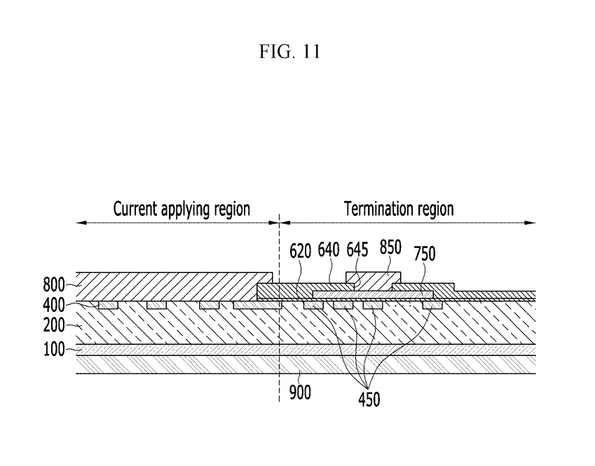

In addition, there may be various structures for the current applying region. This will be described with reference to FIGS. 10 and 11.

FIG. 10 is a diagram illustrating an example of a cross-section of a semiconductor device according to another exemplary embodiment of the present disclosure.

Referring to FIG. 10, the semiconductor device according to the present exemplary embodiment has the same structure of the termination region as that of the semiconductor device of FIG. 1, but has a different structure of the current applying region from that of the semiconductor device of FIG. 1. Accordingly, the description of the termination region will be omitted.

The structure of the current applying region according to the present exemplary embodiment does not include a first trench 210 and a second trench 220, compared to the semiconductor device of FIG. 1.

An n− type layer 200 is disposed on a first surface of an n+ type silicon carbide substrate 100. A plurality of p type regions 400, which are spaced apart from each other, is disposed within the n− type layer 200. The plurality of p type regions 400 may be disposed in an upper portion within the n− type layer 200, and an extended line of an upper surface of the p type region 400 and an extended line of an upper surface of the n− type layer 200 may be disposed on the same line.

An n+ type region 300 and a p+ type region 500 are disposed within the p type region 400. The n+ type region 300 and the p+ type region 500 are disposed to be adjacent to each other, and are disposed in an upper portion within the p type region 400. An extended line of the upper surfaces of the n+ type region 300 and the p+ type region 500 and an extended line of the upper surface of the p type region 400 may be disposed on the same line.

A gate insulating layer 610 is disposed on a part of the n− type layer 200, a part of the n+ type region 300, and a part of the p type region 400. A gate electrode 700 is disposed on the gate insulating layer 610, and an oxidation layer 630 is disposed on the gate electrode 700. The oxidation layer 630 covers a side surface of the gate electrode 700.

A source electrode 800 is disposed on the n+ type region 300, on the oxidation layer 630, on the p+ type region 500, and the p type region 400, and a drain electrode 900 is disposed on a second surface of the n+ type silicon carbide substrate 100. Here, the source electrode 800 and the drain electrode 900 may include an ohmic metal. The second surface of the n+ type silicon carbide substrate 100 is disposed at an opposite side of the first surface of the n+ type silicon carbide substrate 100.

FIG. 11 is a diagram illustrating an example of a cross-section of a semiconductor device according to still another exemplary embodiment of the present disclosure.

Referring to FIG. 11, the semiconductor device according to the present exemplary embodiment has the same structure of the termination region as that of the semiconductor device of FIG. 1, but has a different structure of the current applying region from that of the semiconductor device of FIG. 1. Accordingly, the description of the termination region will be omitted. However, a lower gate runner 750 and an upper gate runner 850 in the termination region may also be integrally formed.

The structure of the current applying region according to the present exemplary embodiment is a diode structure, in which a gate electrode 700 does not exist, compared to the semiconductor device of FIG. 1. Further, a first trench 210 and a second trench 220 do not exist.

An n− type layer 200 is disposed on a first surface of an n+ type silicon carbide substrate 100. A plurality of p type regions 400, which are spaced apart from each other, is disposed within the n− type layer 200. The plurality of p type regions 400 may be disposed in an upper portion within the n− type layer 200, and an extended line of an upper surface of the p type region 400 and an extended line of an upper surface of the n− type layer 200 may be disposed on the same line.

A source electrode 800 is disposed on the n− type layer 200 and on the p type region 400, and a drain electrode 900 is disposed in a second surface of the n+ type silicon carbide substrate 100. Here, the source electrode 800 may serve as an anode, and the drain electrode 900 may serve as a cathode. Further, the source electrode 800 and the drain electrode 900 may include an ohmic metal. The second surface of the n+ type silicon carbide substrate 100 is disposed at an opposite side of the first surface of the n+ type silicon carbide substrate 100.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A semiconductor device, comprising:
a current applying region; and
a termination region disposed at an end portion of the current applying region,
wherein the termination region includes:
an n− type layer disposed on a first surface of an n+ type silicon carbide substrate;
a p type termination structure disposed in the n− type layer; and
a lower gate runner disposed on the p type termination structure such that the lower gate runner overlaps the p type termination structure.

2. The semiconductor device of claim 1, wherein:
the termination region further includes an upper gate runner in contact with the lower gate runner.

3. The semiconductor device of claim 2, wherein:
a p type region, which is disposed in a side surface of a trench adjacent to the termination region, extends to the termination region, and is spaced apart from the p type termination structure.

4. The semiconductor device of claim 3, wherein:
the p type termination structure includes a plurality of regions, and the regions are spaced apart from each other.

5. The semiconductor device of claim 4, wherein:
the current applying region and the termination region include a drain electrode disposed on a second surface of the n+ type silicon carbide substrate.

6. The semiconductor device of claim 5, wherein:
the current applying region further includes:
the n− type layer disposed on the first surface of the n+ type silicon carbide substrate; and
a gate electrode and a source electrode, which are disposed on the n− type layer and are insulated from each other.

7. The semiconductor device of claim 6, wherein:
the gate electrode and the lower gate runner include the same material.

8. The semiconductor device of claim 7, wherein:
the source electrode and the upper gate runner include the same material.

9. The semiconductor device of claim 8, wherein:
the current applying region further includes:
a first trench disposed in the n− type layer;
a p type region disposed in a side surface of the first trench; and
an n+ type region disposed in the side surface of the first trench and disposed within the p type region, and
the gate electrode is disposed within the first trench, and
the source electrode is disposed on the n+ type region, on the gate electrode, and on the p type region.

10. The semiconductor device of claim 9, wherein:
the current applying region further includes a p+ type region, which is disposed within the p type region, and is disposed in a side surface of the n+ type region.

11. The semiconductor device of claim 8, wherein:
the current applying region further includes:
the trench including a first trench and a second trench, which are disposed in the n− type layer, and are spaced apart from each other;
the p type region disposed in a lower portion and both side surfaces of the second trench; and
an n+ type region disposed on the p type region and the n− type layer, and
the gate electrode is disposed within the first trench, and
the source electrode is disposed on the n+ type region, on the gate electrode, and within the second trench.

12. The semiconductor device of claim 11, wherein:
the current applying region further includes a p+ type region disposed between a lower surface of the second trench and the p type region.

13. The semiconductor device of claim 5, wherein:
the current applying region further includes:
the n− type layer disposed on the first surface of the n+ type silicon carbide substrate;
a plurality of p type regions, which are disposed within the n− type layer, and are spaced apart from each other; and
a source electrode disposed on the n− type layer and on the p type region.

14. A method of manufacturing a semiconductor device, the method comprising steps of:
forming an n− type layer on a first surface of an n+ type silicon carbide substrate including a current applying region and a termination region disposed at an end portion of the current applying region;
forming an n+ type region on the n− type layer of the current applying region;
forming a first trench and a second trench, which are spaced apart from each other, in the n− type layer of the current applying region by etching the n+ type region and the n− type layer;
forming a p type region in a lower portion and both side surfaces of the second trench, and forming a p type termination structure in the n− type layer of the termination region;
forming a gate electrode within the first trench, and forming a lower gate runner, which is disposed on the p type termination structure and overlaps the p type termination structure;
forming a source electrode on the n+ type region, on the gate electrode, and within the second trench; and
forming a drain electrode on a second surface of the n+ type silicon carbide substrate.

15. The method of claim 14, wherein:
the p type region, which is disposed in a side surface of the second trench adjacent to the termination region, is extended to the termination region, and is spaced apart from the p type termination structure.

16. The method of claim 15, wherein:
the p type termination structure includes a plurality of regions, and
the regions are spaced apart from each other.

17. The method of claim 16, wherein:
the step of forming the source electrode includes
forming an upper gate runner, which is in contact with the lower gate runner, in the termination region.

18. The method of claim 17, wherein:
the gate electrode and the lower gate runner include the same material.

19. The method of claim 18, wherein:
the source electrode and the upper gate runner include the same material.

20. The method of claim 19, further comprising:
forming a p+ type region disposed between a lower surface of the second trench and the p type region.
